(19) United States
(12) Patent Application Publication
(10) Pub. No.: US 2022/0009253 A1
(43) Pub. Date: Jan. 13, 2022

(54) PRINT DEVICE

(71) Applicant: BROTHER KOGYO KABUSHIKI KAISHA, Nagoya (JP)

(72) Inventors: Takaaki OGUCHI, Nagoya (JP); Kenta HAYASHIDA, Inazawa (JP); Atsuo HIROSE, Nagoya (JP); Robin RIAZI, Kasugai (JP); Keita SUGIURA, Toyokawa (JP); Akito UEKIHARA, Nagoya (JP)

(21) Appl. No.: 17/483,522

(22) Filed: Sep. 23, 2021

Related U.S. Application Data
(63) Continuation of application No. PCT/JP2020/007708, filed on Feb. 26, 2020.

(30) Foreign Application Priority Data
Mar. 29, 2019 (JP) 2019-066986
May 28, 2019 (JP) 2019-099691

(51) Int. Cl. B41J 15/04; B65H 16/02; B41J 29/13

(52) U.S. Cl. CPC B41J 15/048; B41J 29/13; B65H 16/023

(57) ABSTRACT

There is provided a print device including: a casing having an inner space; a support which extends along a first direction and which is configured to rotatably support a roll body; a conveyer configured to convey a sheet pulled out of the roll body in a conveyance orientation along a second direction orthogonal to the first direction; a print unit configured to perform a print by causing a print matter to adhere to the sheet conveyed in the conveyance orientation; and a cover. An opening is provided on the casing such that the inner space is exposed to an outside of the casing via the opening. The cover is configured to slide relative to the casing along the second direction between an open position in which the opening is uncovered and a close position in which the opening is covered by the cover.

### CROSS REFERENCE TO RELATED APPLICATIONS

The present application is a continuation of International Application No. PCT/JP2020/007708 filed on Feb. 26, 2020 which claims priority to Japanese Patent Applications No. 2019-066986 filed on Mar. 29, 2019 and No. 2019-099691 filed on May 28, 2019.

### BACKGROUND

The present disclosure relates to a print device (printing apparatus, printer) which includes a casing (housing) having an opening to be covered (closed) or uncovered (opened) by a cover. The casing has a support member for supporting a roll body, positioned in an inner space of the casing.

For example, there are known printing apparatuses which print on a sheet rolled out or fed out from a roll body. In an inner space of such a printing apparatus, the roll body is supported on a roll body installer. The apparatus case is provided with a roll body supply port. The roll body supply port is opened and closed by pivoting an external cover provided pivotally on the apparatus case.

### SUMMARY

According to one aspect of the present disclosure, there is provided a print device including a casing, a support, a conveyer, a print unit and a cover.

The casing has an inner space.

The support extends along a first direction in the inner space of the casing and is configured to rotatably support a roll body.

The conveyer is configured to convey a sheet pulled out of the roll body supported by the support in a conveyance orientation along a second direction orthogonal to the first direction, in the inner space of the casing.

The print unit is configured to perform a print by causing a print matter to adhere to the sheet conveyed in the conveyance orientation, in the inner space of the casing.

An opening is provided on the casing such that the inner space is exposed to an outside of the casing via the opening.

The cover is configured to slide relative to the casing along the second direction between an open position in which the opening is uncovered and a close position in which the opening is covered by the cover.

With the cover sliding in the second direction, the opening is uncovered or covered. Thus, in the case of setting the roll body onto the support and the like, a comparatively small space is needed, for positioning the cover in the open position, at one side in the first direction of the print device where the inner space of the casing is exposed.

According to another one aspect of the present disclosure, there is provided a print device including a casing, a support, a conveyer, a print unit, a first cover, and a second cover.

The casing has an inner space.

The support extends along a first direction in the inner space of the casing and is configured to rotatably support a roll body.

A conveyer is configured to convey a sheet pulled out of the roll body supported by the support in a conveyance orientation along a second direction orthogonal to the first direction, in the inner space of the casing.

A print unit is configured to perform a print by causing a print matter to adhere to the sheet conveyed in the conveyance orientation, in the inner space of the casing.

An opening is provided on the casing such that the inner space is exposed to an outside of the casing via the opening.

The first cover is configured to slide relative to the casing along the second direction between an open position in which the opening is uncovered and a close position in which the opening is covered by the first cover.

The second cover constitutes at least a portion of an outer wall, of the casing, positioned at one side in the second direction of the casing.

The second cover has one end defining a part of the opening; and

The second cover is configured to change a posture of the second cover relative to the casing.

According to another one aspect of the present disclosure, there is provided a print device including a casing, a support, a print unit and a cover.

The casing has an inner space.

The support extends along a first direction in the inner space of the casing and is configured to rotatably support a roll body.

The print unit is configured to perform a print, in the inner space of the casing, on a sheet pulled out of the roll body supported by the support.

The support is configured to support the roll body such that the roll body rotates on a rotation axis extending in the first direction.

An opening is provided on the casing such that the inner space is exposed to an outside of the casing via the opening.

The cover is configured to move between an open position in which the opening is uncovered and a close position in which the opening is covered by the cover.

The cover includes a plate configured to cover at least a portion of the opening in a case that the cover is positioned in the close position.

The cover is configured to maintain a posture in which an angle between a first plane parallel with the plate of the cover and a second plane parallel with the plate of the cover positioned in the close position is less than 90 degrees throughout a movement from the close position to the open position.

With the cover moving to the open position without inclination of 90 degrees or above with respect to the posture of the cover in the close position, the opening is uncovered or covered. Thus, in the case of setting the roll body onto the support and the like, a comparatively small space is needed, for positioning the cover in the open position, at one side in the first direction of the print device where the inner space of the casing is exposed.

### BRIEF DESCRIPTION OF THE DRAWINGS

FIG. 1 is a perspective view of a print device 10 by the side of a front surface 31 when a slide cover 90 is in close position.

FIG. 2 is a perspective view of the print device 10 by the side of the front surface 31 when the slide cover 90 is in open position.

FIG. 3 is a schematic view of the cross section along the line of FIG. 1.

FIG. 4 is a schematic view depicting a support configuration for a pinch roller 61 when a pin 69 is positioned in a first part 95 of a cam ditch 94.

FIG. 5A is a schematic view depicting that the pin 69 is positioned in a third part 97 of the cam ditch 94.

FIG. 5B is a schematic view depicting that the pin 69 is positioned in a second part 96 of the cam ditch 94.

FIG. 6 is a schematic view of the cross section along the line VI-VI of FIG. 2.

FIG. 7A is a perspective view of the print device 10 when a slide cover pair 901 is in close position.

FIG. 7B is a perspective view of the print device 10 when the slide cover pair 901 is in open position.

FIG. 8A is a perspective view of the print device 10 when a folding-door-type cover 902 is in close position.

FIG. 8B is a perspective view of the print device 10 when the folding-door-type cover 902 is in open position.

FIG. 8C is a plan view of the folding-door-type cover 902 in the close position (unfolded position).

FIG. 8D is a plan view of the folding-door-type cover 902 in between the open position (folded position) and the close position.

FIG. 8E is a plan view of the folding-door-type cover 902 in the open position.

FIG. 9A is a perspective view of the print device 10 when a pivot-type cover 903 is in close position.

FIG. 9B is a perspective view of the print device 10 when the pivot-type cover 903 is in open position.

FIG. 10A is a perspective view of the print device 10 when a shutter-type cover 904 is in close position.

FIG. 10B is a perspective view of the print device 10 when the shutter-type cover 904 is in open position.

FIG. 11A is a perspective view of the print device 10 when the shutter-type cover 904 is in close position.

FIG. 11B is a perspective view of the print device 10 when the shutter-type cover 904 is in open position.

FIG. 12A is a perspective view of the print device 10 when a vertical-slide-type cover 905 is in close position.

FIG. 12B is a perspective view of the print device 10 when the vertical-slide-type cover 905 is in open position.

FIG. 13A is a perspective view of the print device 10 when a link-type cover 906 is in close position.

FIG. 13B is a perspective view of the print device 10 when the link-type cover 906 is in between open position and the close position.

FIG. 13C is a perspective view of the print device 10 when the link-type cover 906 is in the open position.

FIGS. 14A to 14C are schematic views depicting an aspect of movement of a cover 906a and each link member relative to a casing 14, wherein FIG. 14A depicts that the cover 906a is in close position, FIG. 14B depicts that the cover 906a is in between the close position and open position, and FIG. 14C depicts that the cover 906a is in the open position.

FIGS. 15A and 15B are explanatory views for explaining arrangement and movement of a coil spring CS fitted on a first rear link member 906c, wherein FIG. 15A depicts that the coil spring CS biases the first rear link member 906c toward the close position, and FIG. 15B depicts that the coil spring CS biases the first rear link member 906c toward the open position.

FIGS. 16A to 16C are schematic plan views depicting that a cover 90′ according to a comparative example is in close position, in-between position, and open position, respectively.

FIG. 17 is a perspective view of an air outlet port 12 and a vent 93;

FIG. 18 is a schematic view of a sheet guide 45;

FIG. 19 is a perspective view depicting that the casing 14 is provided with a pivot cover 80 pivoting about a pivot shaft 82; and

FIG. 20 is a perspective view depicting that the casing 14 is provided with the pivot cover 80 pivoting about a pivot shaft 83.

### DETAILED DESCRIPTION

In order to pivot the external cover, a space around the print device is needed for the opened cover to stay. The wider the roll body supply port, the larger the external cover. As a result, a wider space is needed around the print device for the external cover. Therefore, in order to install the roll body into the print device, a large space is necessary around the print device.

The present disclosure is made in view of the above situation, and an object thereof is to provide a means for reducing the space needed for installing the roll body into the print device.

According to the present disclosure, it is possible to reduce the space needed for installing the roll body into the print device.

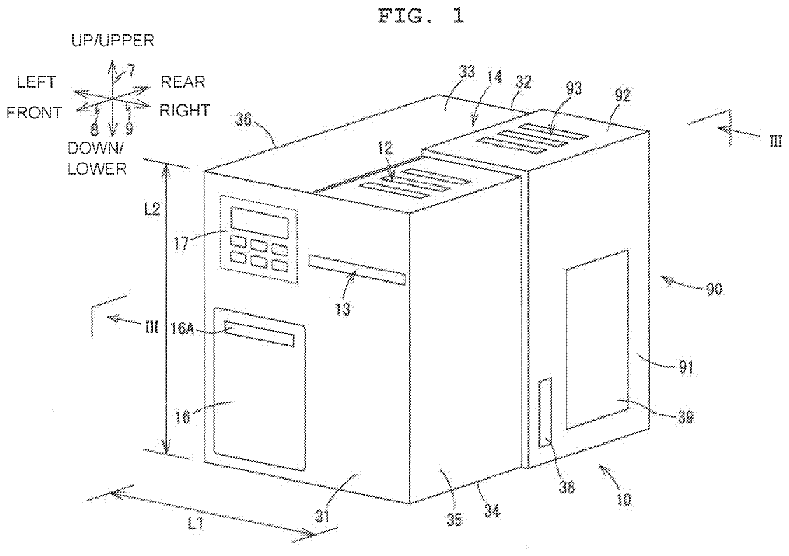

Hereinbelow, an explanation will be made on a print device (printing apparatus, printer) 10 according to an embodiment of the present disclosure. Note that the embodiment explained below is merely one example of the present disclosure and, needless to say, it is possible to change and modify the embodiment as appropriate without departing from the true spirit and scope of the present disclosure. Further, in the following explanation, an orientation is expressed by an arrow proceeding from start point to end point whereas a direction is expressed by an arrow moving to and from on the line linking the start point and the end point. Further, in the following explanation, an up/down direction 7 is defined on the basis of the print device 10 being placed under a usable condition (the condition of FIG. 1), a front/rear direction 8 is defined with a discharge port 13 being provided on the near side (the front side), and a left/right direction 9 is defined with the print device 10 being viewed from the near side (the front side).

[Outer Appearance Configuration of the Print Device 10]

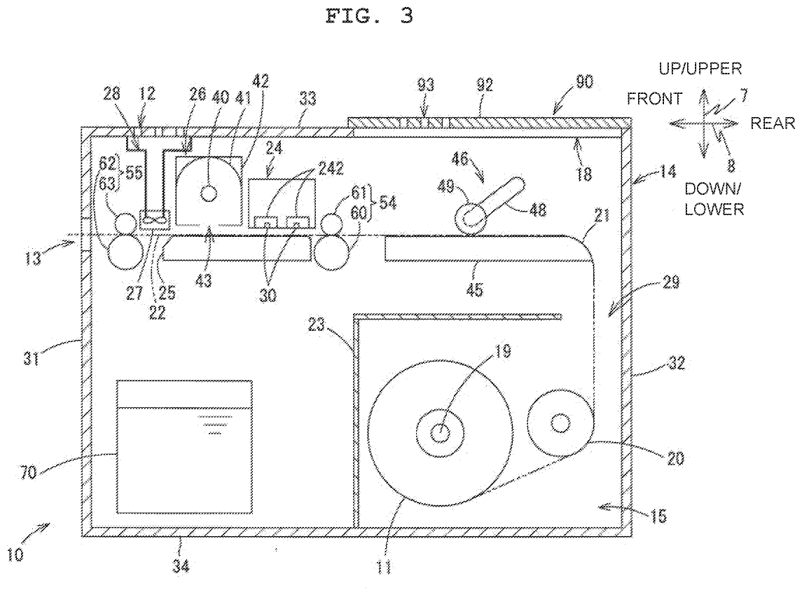

As depicted in FIG. 1, the print device 10 records images onto a roll body 11 (see FIG. 3) or the like by an ink jet recording method. A casing 14 has a right surface 35 (an example of the first surface) and a left surface 36 (an example of the second surface) positioned apart in the left/right direction (an example of the first direction), an upper surface 33 (an example of the third surface) and a lower surface 34 (an example of the fourth surface) positioned apart in the up/down direction 7 (an example of the third direction) to link the right surface 35 and the left surface 36, and an front surface 31 (an example of the fifth surface) and a rear surface 32 (an example of the sixth surface) positioned apart in the front/rear direction 8 (an example of the second direction) to link the upper surface 33 and the lower surface 34.

In the casing 14, a distance L2 between the upper surface 33 and the lower surface 34 is longer than a distance L1 between the right surface 35 and the left surface 36. The casing 14 is almost a cuboid in shape and sized as placeable on a desk. That is, the print device 10 is suitable for being put on a desk in use. Of course, the print device 10 may also be placed on a floor in use.

The discharge port 13 is formed in the front surface 31 of the casing 14. The discharge port 13 is positioned in an upper right part of the front surface 31. An operator panel 17 is positioned on the left to the discharge port 13 on the front surface 31. The operator panel 17 has, for example, a display, input keys, and the like. A user performs inputs on the operator panel 17 for fixing various settings and/or actuating the print device 10.

The front surface 31 is provided with a cover 16 below the operator panel 17. A handle 16A is provided at the upper end of the front surface of the cover 16. The handle 16A projects from or hollows into the front surface of the cover 16. The handle 16A is provided for hooking the user's finger in handling the cover 16. The cover 16 is supported on the casing 14 by its lower end to be pivotable on an axial line along the left/right direction 9. With the cover 16 being opened, the inner space of the casing 14 is exposed through a through hole. A tank 70 (see FIG. 3) is positioned at the rear to the cover 16. The outer surface of the closed cover 16 is part of the front surface 31 of the casing 14.

A plurality of air outlets 12 are formed in the upper surface 33 of the casing 14. The air outlets 12 are configured to align in the front/rear direction 8, with those long holes extending elongate in the left/right direction 9 and penetrating through the casing 14. The air outlets 12 are positioned above a fan 27 (see FIG. 3).

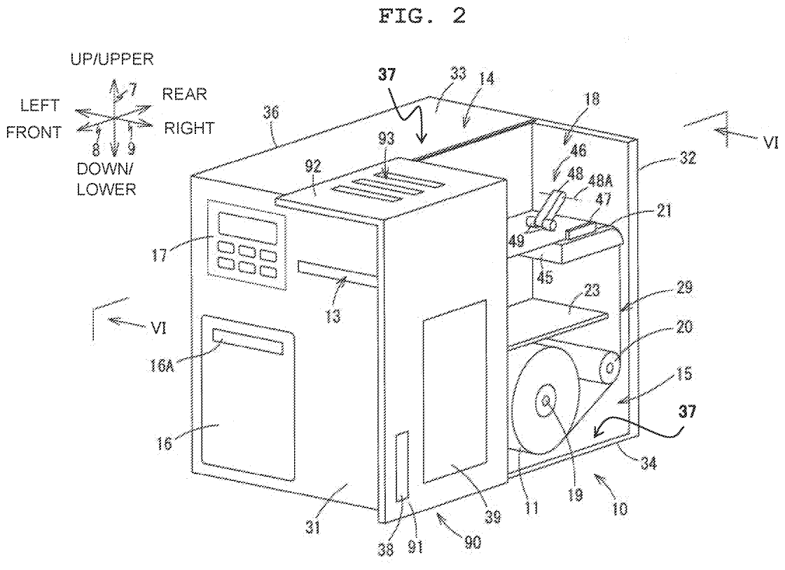

As depicted in FIG. 2, an opening 18 is formed across the upper surface 33 and the right surface 35 of the casing 14. The opening 18 is positioned on the rear to the approximately center of the right surface 35 in the front/rear direction 8, across almost the entire area in the up/down direction 7. Further, the opening 18 is positioned on the rear to the approximately center in the front/rear direction 8 and on the right to the approximately center in the left/right direction 9, in the upper surface 33. The opening 18 opens the inner space of the casing 14 in the two directions of the up/down direction 7 and the left/right direction 9.

The casing 14 is provided with a slide cover 90 (an example of the cover) to open (uncover) and close (cover) the opening 18. The slide cover 90 is able to slide on the casing 14 along the front/rear direction 8. The casing 14 is provided with a guide rail 37 extending along the front/rear direction 8 to support the slide cover 90 in a slide-able manner. The slide cover 90 opens (uncovers) the opening 18 in open position (see FIG. 2) and closes (covers, blocks) the opening 18 in close position on the rear to the open position in the front/rear direction 8 (see FIG. 1).

The slide cover 90 has approximately an L-shaped cross section along the left/right direction 9 and the up/down direction 7. The slide cover 90 has a cover right surface 91 (an example of the seventh surface) parallel to the right surface 35 of the casing 14, and a cover upper surface 92 (an example of the eighth surface) parallel to the upper surface 33 of the casing 14. When the slide cover 90 is in the close position, the cover right surface 91 covers up the opening 18 in the right surface 35 of the casing 14. When the slide cover 90 is in the close position, the cover upper surface 92 covers up the opening 18 in the upper surface 33 of the casing 14.

The cover upper surface 92 of the slide cover 90 is formed with a plurality of vents 93. The vents 93 are configured to align in the front/rear direction 8, with those long holes extending elongate in the left/right direction 9 and penetrating through the slide cover 90. The shape and arrangement (pitch) of the respective long holes of the vents 93 are the same as the shape and arrangement (pitch) of the respective long holes of the air outlets 12. When the slide cover 90 is in the close position, the vents 93 are positioned on the rear to the printing head 24 in the front/rear direction 8.

The cover right surface 91 of the slide cover 90 is provided with a handle 38 and a window 39. The handle 38 projects from or hollows into the cover right surface 91. The handle 38 is provided for hooking the user's finger in handling the slide cover 90. The window 39 is a transparent member for blocking the through hole penetrating through the slide cover 90. The window 39 is provided for observing the roll body 11 positioned in the inner space of the casing 14 from the outside.

[Internal Configuration of the Print Device 10]

As depicted in FIG. 3, a conveyance path 22 is formed in the inner space of the casing 14. In the inner space of the casing 14, there are arranged the roll body 11, a feed roller 20, a sheet guide 45, a first conveyance roller pair 54, a second conveyance roller pair 55, a platen 25, a heater 26, the fan 27, and a tank 70. Note that albeit being undepicted in the figure, in the inner space of the casing 14, other members may also be arranged: for example, a maintenance unit such as a cap covering a nozzle surface of the printing head 24, a wiper to wipe the nozzle surface and the like, a control substrate, power circuits, etc.

The printing head 24 (an example of the print unit) is provided with a discharge module 242. In the discharge module 242, a plurality of nozzles 30 are arranged to align in the left/right direction 9. From the plurality of nozzles 30, ink droplets are discharged downward toward the platen 25. Note that in FIG. 3, although only two nozzles 30 are depicted as apart in the front/rear direction 8, the plurality of nozzles 30 may align in the left/right direction 9 and align in the front/rear direction 8 in numbers not less than two.

As depicted in FIG. 3, the tank 70 is positioned on the rear to the cover 16 in the inner space of the casing 14. The tank 70 stores an ink. Albeit being undepicted, the ink is supplied to the printing head 24 from the tank 70 through a tube.

The ink is some liquid containing a pigment and the like. The ink has a viscosity suitable for dispersing the pigment uniformly. The pigment presents a color of the ink. The heater 26 causes the ink printed on a sheet to dry by way of heating. By virtue of this, it is possible to raise the speed of conveying the sheet.

As depicted in FIG. 3, the inner space of the casing 14 has a sheet accommodation space 15 capable of accommodating the roll body 11. The sheet accommodation space 15 is formed in a rear part of the inner space of the casing 14. The sheet accommodation space 15 is defined by a partition wall 23.

In the sheet accommodation space 15, a spindle 19 (an example of the support) is positioned to extend in the left/right direction 9. The spindle 19 supports the roll body 11. The spindle 19 is rotated following a rotation transmitted from an undepicted motor. The rotation of the spindle 19 brings the roll body 11 supported on the spindle 19 to rotate along.

In the sheet accommodation space 15, the roll body 11 is accommodated with the left/right direction 9 as the roll axis direction. The sheet accommodation space 15 opens upward in a rear part. Between the partition wall 23 and the rear surface 32, an interspace 29 is formed through which the sheet pulled out of (fed out from) the roll body 11 is passable.

The feed roller 20 is positioned in the sheet accommodation space 15. The feed roller 20 is an elongate roller with the left/right direction 9 as the axial direction. The sheet pulled out of the roll body 11 to the rear is rolled on the feed roller 20 to extend upward.

The sheet guide 45 is positioned above the feed roller 20. The sheet guide 45 is plate (flat plate)-shaped. The upper surface of the sheet guide 45 extends along the front/rear direction 8 and the left/right direction 9, its rear end forming a curved surface 21 facing the rear. The upper surface of the sheet guide 45 is leveled as equal to the discharge port 13 in the up/down direction 7. The sheet is supported on the upper surface of the sheet guide 45. A side guide 47 is positioned on the upper surface of the sheet guide 45. The side guide 47 projects upward above the upper surface of the sheet guide 45 for the surface positioned inside in the left/right direction 9 (the surface facing the left) to extend along the front/rear direction 8. The side guide 47 is movable along the left/right direction 9 with respect to the sheet guide 45. The side guide 47 is moved according to the size of the sheet along the left/right direction 9. The right end of the sheet in the left/right direction 9 is positioned by the surface of the side guide 47 on the inside.

A presser member 46 is positioned above the sheet guide 45. The presser member 46 has an arm 48 and a roller 49. The upper end of the arm 48 is supported pivotally by the casing 14 and the like, and the lower end extends downward and frontward. The arm 48 is pivotable with an axial line 48A as the center. Note that in FIG. 2, the member supporting the arm 48 is omitted in illustration. The roller 49 is rotatably supported at the lower end of the arm 48. The axis of the roller 49 is parallel to the axial line 48A of the arm 48. Between the roller 49 and the upper surface of the sheet guide 45, the sheet pulled out of the roll body 11 is passable.

As depicted in FIG. 3, the conveyance path 22 is formed across the sheet guide 45 and the discharge port 13. The conveyance path 22 extends almost linearly. The conveyance path 22 is a space through which the sheet is passable. Albeit being undepicted in detail in each figure, the conveyance path 22 is defined by guide members positioned apart in the up/down direction 7, the sheet guide 45, the printing head 24, the platen 25, the heater 26, and the like. In the conveyance path 22, the frontward orientation is the conveyance orientation.

As depicted in FIG. 3, the first conveyance roller pair 54 (an example of the conveyer) is provided upstream to the printing head 24 in the conveyance path 22 in the conveyance orientation. The first conveyance roller pair 54 has a first conveyance roller 60 and a pinch roller 61. In the conveyance path 22, the second conveyance roller pair 55 (another example of the conveyer) is provided downstream from the heater 26 in the conveyance orientation. The second conveyance roller pair 55 has a second conveyance roller 62 and a pinch roller 63. The first conveyance roller 60 and the second conveyance roller 62 are rotated by a motor (not depicted) whose rotation is transmitted thereto. The pinch roller 61 is biased toward the first conveyance roller 60 while the pinch roller 63 is biased to the second conveyance roller 62. The first conveyance roller pair 54 and the second conveyance roller pair 55 convey the sheet in the conveyance orientation by rotating the first conveyance roller 60 and the second conveyance roller 62 in a state that the sheet extending from the roll body 11 is nipped between the respective rollers constituting those roller pairs.

The structure for the pinch roller 61 to be biased toward the first conveyance roller 60 is the same as the structure for the pinch roller 63 to be biased toward the second conveyance roller 62. Therefore, details will be explained below with an example where the pinch roller 61 is biased toward the first conveyance roller 60.

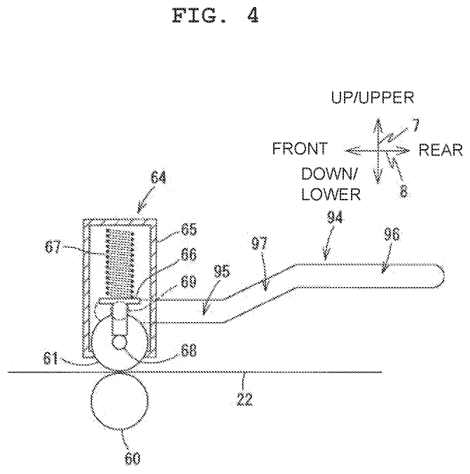

As depicted in FIG. 4, the pinch roller 61 is positioned above the first conveyance roller 60. The pinch roller 61 is supported rotatably by a roller holder 64. The roller holder 64 has a holder casing 65, a shaft presser member 66, and a coil spring 67. The holder casing 65 is hollow. Part of the pinch roller 61 is accommodated in the inner space of the holder casing 65. The shaft 68 of the pinch roller 61 is supported rotatably by the holder casing 65. Being supported by the holder casing 65, the shaft 68 is movable in a predetermined range in the up/down direction 7. The lower surface of the holder casing 65 has an opening through which part of the pinch roller 61 projects downward from the holder casing 65.

The shaft presser member 66 is positioned in the inner space of the holder casing 65. The shaft presser member 66 is positioned above the shaft 68 of the pinch roller 61, being contactable with the shaft 68. The shaft presser member 66 is movable along the up/down direction 7 in the inner space of the holder casing 65.

The coil spring 67 is positioned in the inner space of the holder casing 65. The coil spring 67 can be contractedly deformed along the up/down direction 7. Being contractedly deformed, the coil spring 67 is in contact with the holder casing 65 at the upper end such that its lower end is in contact with the shaft presser member 66. Due to the elasticity of the coil spring 67, the shaft 68 of the pinch roller 61 is biased downward via the shaft presser member 66.

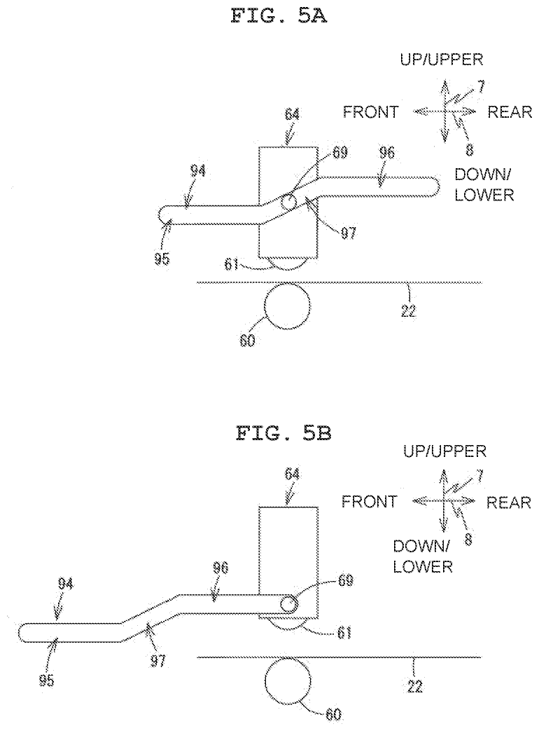

As depicted in FIG. 5A and FIG. 5B, the holder casing 65 has a pin 69 projecting toward the slide cover 90 along the left/right direction 9. The pin 69 functions as a cam follower fitted in a cam ditch 94. The pin 69 and the cam ditch 94 are an example of the cam mechanism.

As depicted in FIGS. 5A and 5B, the cam ditch 94 is formed in such an inner surface of the slide cover 90 as positioned on the other side than the cover right surface 91. The cam ditch 94 has a first part 95 extending in the front/rear direction 8, a second part 96 positioned above and on the rear to the first part 95 to extend in the front/rear direction 8, and a linear third part 97 connecting the rear end of the first part 95 and the front end of the second part 96. In the up/down direction 7, the first part 95 and the second part 96 are farther apart than the range for the pinch roller 61 to be movable relative to the holder casing 65 along the up/down direction 7. Corresponding to the position of the slide cover 90, the pin 69 moves between the first part 95, the second part 96 and the third part 97 of the cam ditch 94.

As depicted in FIG. 4, when the slide cover 90 is in the close position, the pin 69 is positioned in the first part 95 of the cam ditch 94. When the slide cover 90 is positioned in the first part 95, the pinch roller 61 is in contact with the first conveyance roller 60.

As depicted in FIG. 5A, in the course of the slide cover 90 being slid from the close position to the open position, the pin 69 comes from the first part 95 into the third part 97. With the pin 69 heading for the second part 96 along the third part 97, the pin 69 moves upward in the up/down direction 7. With the pin 69 moving upward, the holder casing 65 also moves upward. Further, when the shaft 68 of the pinch roller 61 is positioned at the lower end as movable relative to the holder casing 65, the pinch roller 61 also moves upward along with the moving holder casing 65. Then, before the pin 69 positioned in the third part 97 arrives in the second part 96, the pinch roller 61 departs (detaches) from the first conveyance roller 60.

As depicted in FIG. 5B, when the slide cover 90 is in the open position, the pin 69 is positioned in the second part 96 of the cam ditch 94. When the pin 69 is positioned in the second part 96, the pinch roller 61 is kept away from the first conveyance roller 60. Note that if the slide cover 90 moves from the open position to the close position, then in the opposite orientation to the earlier description, the pin 69 comes from the second part 96 into the third part 97 and reaches the first part 95.

As depicted in FIG. 3, the printing head 24, the platen 25, the heater 26, and the fan 27 are positioned in the conveyance path 22 between the first conveyance roller pair 54 and the second conveyance roller pair 55.

As depicted in FIG. 3, the platen 25 is positioned below the printing head 24. The upper surface of the platen 25 is parallel to the surface of the printing head 24 with the respective nozzles 30 opening therein. The upper surface of the platen 25 is sized along the left/right direction 9 to be larger than the roll body 11 along the left/right direction 9. The platen 25 supports the sheet on the upper surface for the first conveyance roller pair 54 and the second conveyance roller pair 55 to convey the same thereupon. Albeit being not depicted in the figure, a negative pressure or static electricity may be applied to fasten the sheet on the upper surface of the platen 25.

As depicted in FIG. 3, in an upper part of the conveyance path 22, the heater 26 is positioned downstream from the printing head 24 and upstream to the second conveyance roller pair 55. The heater 26 is a so-called halogen heater. The heater 26 has a halogen lamp 40 being a heating body radiating infrared rays, a reflector plate 41, and a casing 42. The casing 42 is almost cuboid-shaped. An opening 43 is formed in the lower wall of the casing 42 along the left/right direction 9. Through the opening 43, the infrared light is radiated to the outside from the halogen lamp 40 and the reflector plate 41.

The halogen lamp 40 is positioned in the inner space of the casing 42. The halogen lamp 40 is shaped into an elongate cylinder, with the left/right direction 9 as the longitudinal direction. In the inner space of the casing 42, the reflector plate 41 is positioned above the halogen lamp 40. The reflector plate 41 is a metallic plate coated with a ceramic film or the like and curved into an arc shape with the central axis defined in the vicinity of the opening 43. Note that instead of the reflector plate 41, the halogen lamp 40 may be used after being coated with a ceramic film or the like.

The heater 26 heats at least one of the sheet passing below the opening 43 and the ink adhered to that sheet (that is, the sheet and/or the ink adhered to the sheet). In this embodiment, the heater 26 heats both the sheet and the ink. By virtue of this, the ink adhered to the sheet is dried.

As depicted in FIG. 3, the fan 27 is positioned in an upper part of the conveyance path 22, downstream from the heater 26 and upstream to the second conveyance roller pair 55. A duct 28, through which air is passable, is provided to connect the fan 27 and the air outlet port 12 of the upper surface 33 of the casing 14. The fan 27 rotates to let the air around the heater 26 in the inner space of the casing 14 flow into the duct 28, and then be discharged to the outside through the air outlet port 12.

[Operation of the Print Device 10]

Hereinbelow, an explanation will be made on an image recording operation of the print device 10.

On receiving a print data, the print device 10 controls an undepicted motor to rotate the spindle 19, the feed roller 20, the first conveyance roller 60, and the second conveyance roller 62. Further, from a power source circuit, electric power is applied to the halogen lamp 40 of the heater 26, and the fan 27. By virtue of this, the leading end of the sheet of the roll body 11 is sent out below the printing head 24. The sheet of the roll body 11 being sent out lets its outward surface in the radial direction of the roll face the printing head 24 and the heater 26. Then, the print device 10 causes the respective rollers to rotate, and the printing head 24 to discharge the ink onto the sheet on the basis of the print data.

The ink droplets discharged from the printing head 24 come to adhere to the sheet supported on the platen 25. If the sheet with the ink droplets adhering thereto reaches below the heater 26, then it is heated by the heater 26. The heater 26 heats the same to fix the ink droplets on the sheet.

The printing apparatus 10 conveys the sheet, until the printed part of the sheet pulled out of the roll body 11 has come out of the casing 14 through the discharge port 13, according to the determination that the printing on the basis of the print data is finished. Thereafter, the print device 10 controls the undepicted motor to stop the spindle 19, the feed roller 20, the first conveyance roller 60, and the second conveyance roller 62 from rotation. Further, the printing apparatus 10 stops the power circuit from providing the power to the halogen lamp 40 of the heater 26. Further, the print device 10 stops the power circuit from providing the power to the fan 27 after the fan 27 is driven over a predetermined time for eliminating the residual heat of the heater 26.

[Replacing the Roll Body 11]

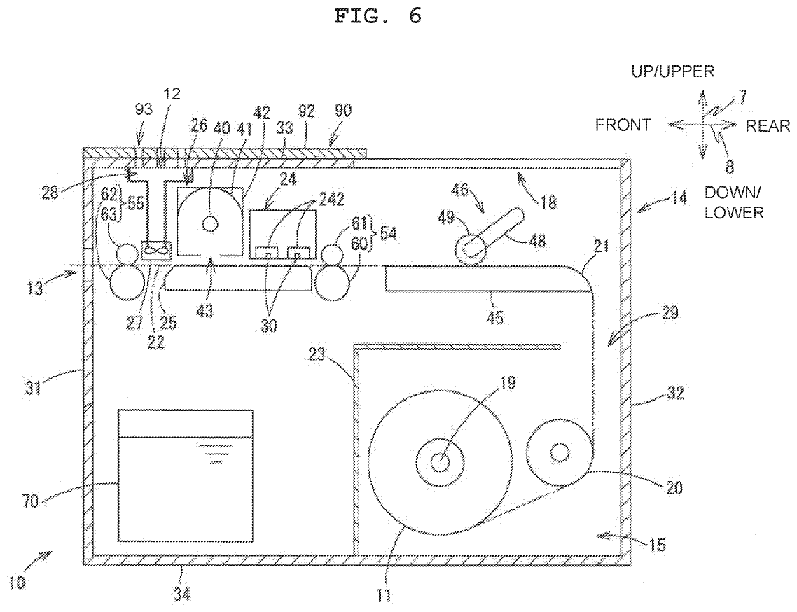

How to replace the roll body 11 will be explained below. If sheets are used in printing and all sheets are pulled out of the roll body 11 supported on the spindle 19, then the user needs to replace the roll body 11. For replacing the roll body 11, the user slides the slide cover 90 in the close position depicted in FIGS. 1 and 3 to the front in the front/rear direction 8, to set the slide cover 90 in the open position depicted in FIGS. 2 and 6. By virtue of this, through the opening 18 of the casing 14, part of the inner space of the casing 14 is exposed.

As depicted in FIG. 2, when the slide cover 90 is in the open position, through the opening 18, the sheet accommodation space 15, the right end of the spindle 19, and the sheet guide 45 are exposed to the outside. On the other hand, because the printing head 24, the platen 25, the heater 26, and the fan 27 are positioned on the front to the opening 18 in the front/rear direction 8, even with the slide cover 90 being in the open position, those members are not exposed to the outside through the opening 18.

As depicted in FIG. 6, when the slide cover 90 is in the open position, the vent 93 formed in the cover upper surface 92 of the slide cover 90 is positioned right above the air outlet port 12 formed in the upper surface 33 of the casing 14. With the air outlet port 12 overlapping with the vent 93, the air discharged from the air outlet port 12 through the duct 28 from the driven fan 27 passes through the vent 93 to reach above the cover upper surface 92.

The user moves the roll body 11 used up through the opening 18 to the right to the spindle 19, and removes the roll body 11 used up from the spindle 19. Then, the user puts a new roll body 11 to the right to the right end of the spindle 19 and moves the new roll body 11 leftward, so as to install the new roll body 11 onto the spindle 19 while accommodating the new roll body 11 into the sheet accommodation space 15.

Then, the user draws out the sheet of the new roll body 11 installed on the spindle 19, sets the sheet on the feed roller 20 and, furthermore, lets the sheet pass through between the upper surface of the sheet guide 45 and the roller 49 of the presser member 46, so as to draw out the leading end of the sheet up to the first conveyance roller pair 54. As described earlier on, because the pinch roller 61 is away from the first conveyance roller 60 when the slide cover 90 is in the open position, the leading end of the sheet is let to pass between the first conveyance roller 60 and the pinch roller 61.

Then, the user slides the slide cover 90 in the open position to set the slide cover 90 to the close position whereby the sheet drawn out from the roll body 11 is nipped by the first conveyance roller 60 and the pinch roller 61.

[Functions and Effects of the Embodiment]

According to the embodiment described above, the opening 18 of the casing 14 is opened or closed by sliding the slide cover 90 in the front/rear direction 8. Thus, when the roll body 11 is installed onto the spindle 19 or when some operation is performed for solving a sheet jam problem, etc., there is a comparatively small space needed on the right to the print device 10 for setting the slide cover 90 to the open position.

Further, because the opening 18 of the casing 14 is continuously provided through the right surface 35 and the upper surface 33, when the slide cover 90 is in the open position, it is possible to access the inner space of the casing 14 from both the up/down direction 7 and the left/right direction 9 through the opening 18.

Further, when the slide cover 90 is in the open position, through the overlapping air outlet port 12 and the vent 93, the air in the inner space of the casing 14 sent out by the fan 27 is discharged to the outside.

Further, if the slide cover 90 is slid from the close position to the open position, then the first conveyance roller 60 is away from the pinch roller 61. Thus, it is easy to position the sheet drawn out from the roll body 11 between the first conveyance roller 60 and the pinch roller 61.

[Modified Embodiments]

In the above embodiment, the slide cover 90 can slide along the front/rear direction 8 to the open position on the front to the close position. However, the slide cover 90 may slide in the front/rear direction 8 to an open position on the rear to the close position.

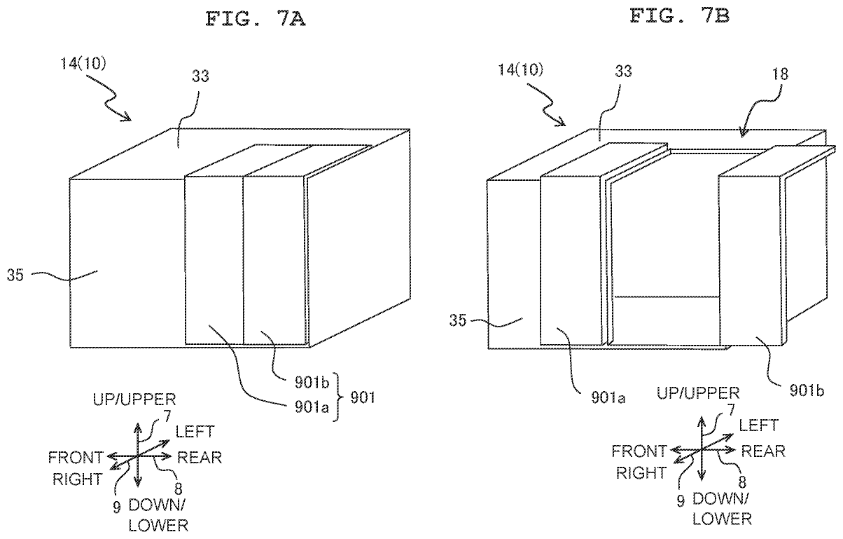

In the above embodiment, the slide cover 90 formed integrally into an L-shape in cross section opens and closes the opening 18 provided in the upper surface 33 and the right surface 35 of the casing 14. However, without being limited to that, the shape of an opening in the casing 14, and the cover opening and closing the opening are allowed for various configurations. Several modified embodiments will be exemplified as follows. Note that in FIGS. 7B, 8B, 9B, 10B, 11B, 12B, and 13C which will be mentioned later on, various structures in the casing 14 will be omitted in illustration.

(1) Dual-Open-Type Cover

In order to open and close the opening 18 of the casing 14, it is possible to use a slide cover pair 901 including a front slide cover 901a and a rear slide cover 901b (FIGS. 7A and 7B). The front slide cover 901a and the rear slide cover 901b are each sized about half of the slide cover 90 in the front/rear direction 8, and are L-shaped in cross section on a plane orthogonal to the front/rear direction 8.

The front slide cover 901a and the rear slide cover 901b are each supported by guide rails (not depicted) to be capable of sliding (moving) in a direction extending within a plane orthogonal to the left/right direction 9 or, in particular, along the front/rear direction 8.

The slide cover pair 901 closes the opening 18 (in the close position; FIG. 7A) with the rear edge of the front slide cover 901a in contact with the front edge of the rear slide cover 901b. The slide cover pair 901 opens the opening 18 (in the open position; FIG. 7B) with the front slide cover 901a being positioned on the front to the opening 18 and the rear slide cover 901b being positioned on the rear to the opening 18.

The slide cover pair 901 may be configured such that if the front slide cover 901a is slid to the front, then the rear slide cover 901b may slide to the rear according to the movement of the front slide cover 901a. In particular, for example, gears are arranged between two rack teeth: one rack tooth fixed on the front slide cover 901a to extend rearward whereas the other rack tooth fixed on the rear slide cover 901b to extend frontward.

(2) Folding-Door-Type Cover

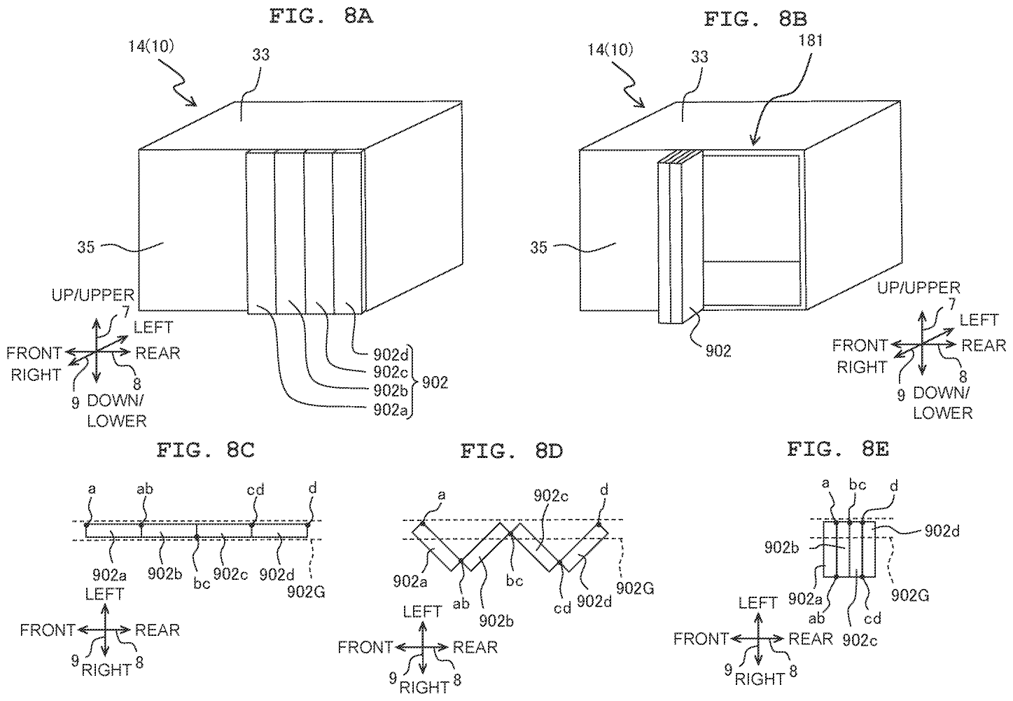

A rectangular opening 181 may be provided in an area being almost the rear half of the right surface 35 of the casing 14 for a folding-door-type cover 902 (FIGS. 8A and 8B) to open and close the opening 181. The opening 181 may be provided such that the printing head 24, the platen 25, the heater 26, and the fan 27 are positioned on the front to the opening 181 in the front/rear direction 8, like the opening 18.

The folding-door-type cover 902 has a configuration of linking rectangular plate (flat plate) -like covers 902a, 902b, 902c, and 902d with the up/down direction 7 as the longitudinal direction and with the front/rear direction 8 as the latitudinal direction. Just as depicted in FIG. 8C, the long side of the cover 902a on the left rear side is linked with the long side of the cover 902b on the left front side through a linking part ab, pivotally with the up/down direction 7 as the axial direction. Similarly, the long side of the cover 902b on the right rear side is linked with the long side of the cover 902c on the right front side through a linking part bc, pivotally with the up/down direction 7 as the axial direction, and the long side of the cover 902c on the left rear side is linked with the long side of the cover 902d on the left front side through a linking part cd, pivotally with the up/down direction 7 as the axial direction.

In the folding-door-type cover 902, a front edge a (FIG. 8C) of the cover 902a positioned frontmost among the covers 902a to 902d is attached to the right surface 35, pivotally with the up/down direction 7 as the axial direction, on the front to the opening 181.

The folding-door-type cover 902 is supported by guide rails 902G arranged along the front/rear direction 8 at the top and the bottom of the folding-door-type cover 902 (FIGS. 8C to 8E), so as to be capable of sliding (moving) in a direction extending within a plane orthogonal to the left/right direction 9 or, in particular, in the front/rear direction 8 (FIGS. 8C to 8E).

The folding-door-type cover 902 closes the opening 181 (in the close position; FIGS. 8A and 8C) with the covers 902a to 902d being disposed on one plane. The folding-door-type cover 902 opens the opening 181 (in the open position; FIGS. 8B and 8E) with the rectangular covers 902a to 902d being disposed to overlap with each other in a folded state.

The folding-door-type cover 902 may be fitted on the casing 14 via a rear edge d of the cover 902d positioned on the rearmost among the covers 902a to 902d, at the rear of the opening 181. In such case, with the opening 181 being opened, the folded folding-door-type cover 902 is positioned at the rear of the opening 181. Therefore, the user positioned on the front to the casing 14 can more easily access the opening 181. Note that the number of covers constituting the folding-door-type cover 902 is not limited to four but is arbitrary.

(3) Pivot-Type Cover

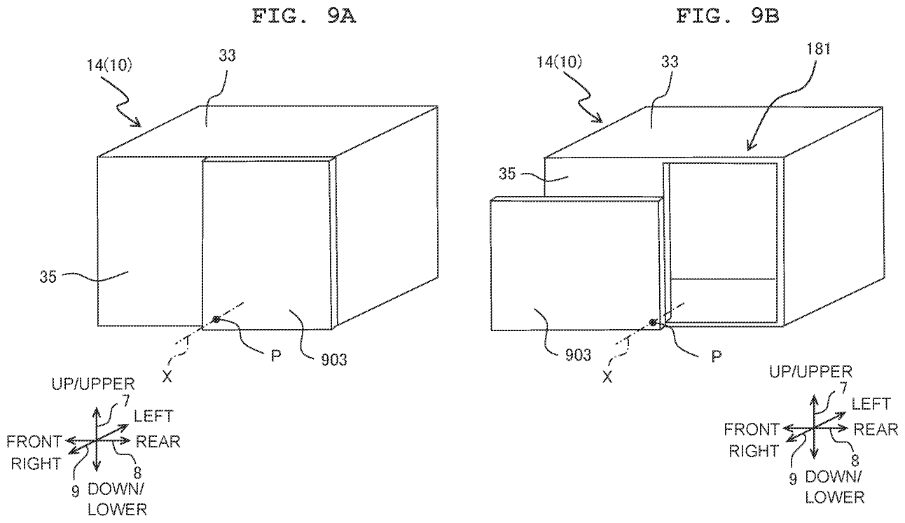

In order to open and close the opening 181 of the casing 14, it is possible to use a pivot-type cover 903 (FIGS. 9A and 9B). The pivot-type cover 903 is a rectangular plate. The pivot-type cover 903 is linked to the right surface 35 of the casing 14 via a pivotal pin P extending in the left/right direction 9 in the state that its thickness direction is brought along the left/right direction 9 (that is, the plate (flat plate)-like pivot-type cover 903 is orthogonal to the left/right direction 9).

The pivot-type cover 903 pivots on the casing 14 with a shaft X extending in the left/right direction 9 along the pivotal pin P as the pivot center. The pivot-type cover 903 pivots (moves) in a direction extending within a plane orthogonal to the left/right direction 9 while keeping a state in which the thickness direction of the pivot-type cover 903 matches the left/right direction 9.

The pivot-type cover 903 closes the opening 181 (in the close position; FIG. 9A) in a standing state in which the long sides of the pivot-type cover 903 extend along the up/down direction 7. The pivot-type cover 903 opens the opening 181 (in the open position; FIG. 9B) in a lying state in which the long sides of the pivot-type cover 903 extend along the front/rear direction 8.

Note that in FIGS. 9A and 9B, the pivot-type cover 902 is linked to the casing 14 at the corner positioned on the front lower side in the standing state. However, without being limited to that, the pivot-type cover 902 may be linked with the casing 14 in any position as far as it is possible to open and close the opening 181 by way of pivoting the pivot-type cover 902. Further, part of the pivot-type cover 902 may be removed as appropriate such that the floor may not interfere when the pivot-type cover 902 is pivoted.

(4) Shutter-Type Cover

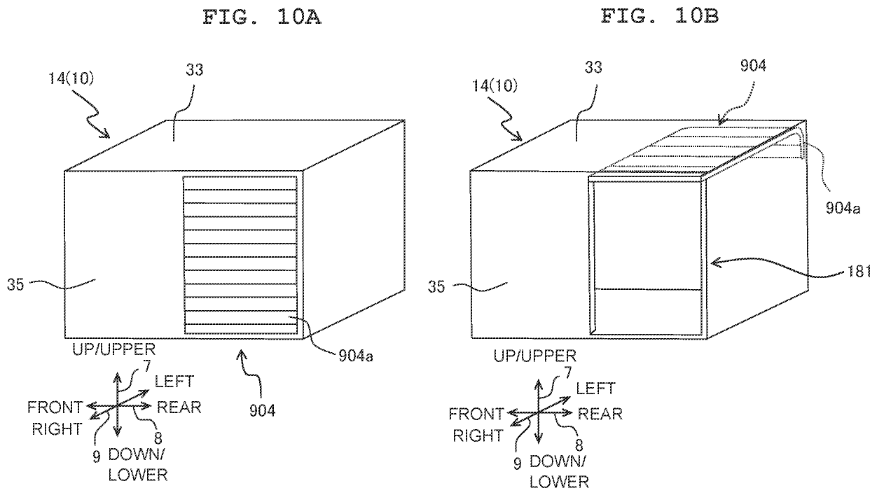

In order to open and close the opening 181, it is possible to use a shutter-type cover 904 (FIGS. 10A and 10B). The shutter-type cover 904 is configured to be shutter-like with a number of slats 904a each shaped as an elongated rectangular plate, the longer sides of the slats 904a being linked with each other pivotally.

The shutter-type cover 904 is supported by a pair of guide rails (not depicted) arranged in a front edge part and a rear edge part of the opening 181, to be movable in the up/down direction 7 and the left/right direction 9. In this case, the shutter-type cover 904 moves in the up/down direction 7 (that is, the direction extending within a plane orthogonal to the left/right direction 9) while keeping a state in which the thickness direction of the shutter-type cover 904 matches the left/right direction 9.

The shutter-type cover 904 is arranged within the plane orthogonal to the left/right direction 9, in the pulled down position (in the close position; FIG. 10A) so as to close the opening 181. The shutter-type cover 904 is disposed almost parallel to the upper surface 33 in a little lower position than the upper surface 33 in the casing 14, in the lifted up position (in the open position; FIG. 10B).

Note that with changed positions of the guide rails, it is possible to configure the shutter-type cover 904 in the lifted up position to be arranged almost parallel to the upper surface 33 in a little higher position than the upper surface 33 (that is, on the outside of the casing 14).

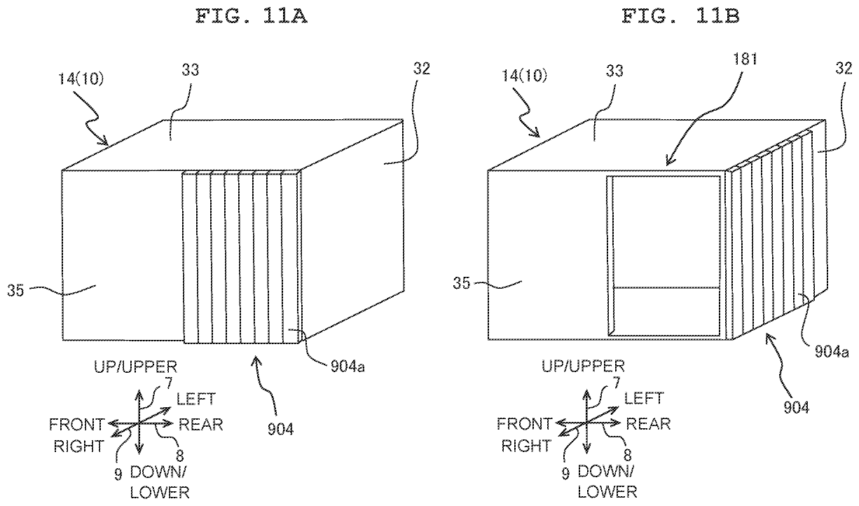

In addition, the shutter-type cover 904 may be supported by a pair of guide rails (not depicted) arranged in an upper edge part and a lower edge part of the opening 181, in a movable manner in the front/rear direction 8 and the left/right direction 9 (FIGS. 11A and 11B). In such case, the shutter-type cover 904 is arranged within the plane orthogonal to the left/right direction 9 in the forward position (in the close position; FIG. 11A) so as to close the opening 181, and is arranged almost parallel to the rear surface 32 on the rear to the rear surface 32 in the casing 14, in the backward position (in the open position; FIG. 11B).

(5) Vertical-Slide-Type Cover

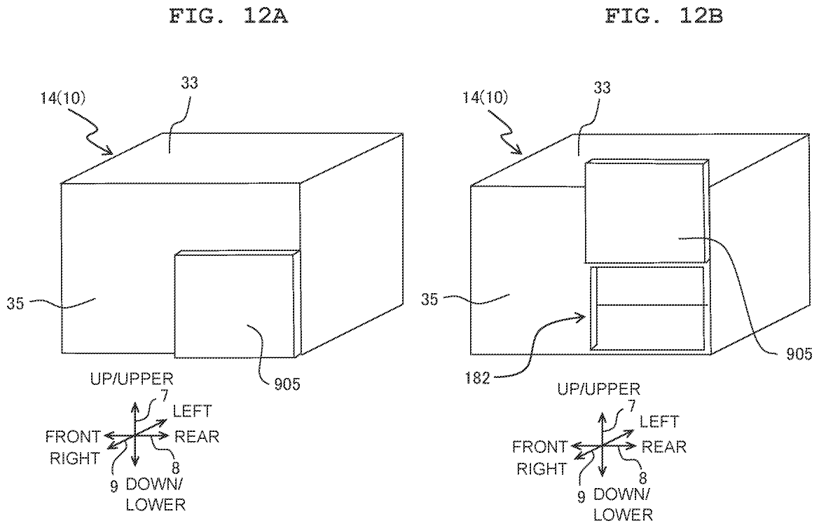

A rectangular opening 182 may be provided in an area of almost the rear half and almost the lower half of the right surface 35 of the casing 14, to let a vertical-slide-type cover 905 open and close the opening 182 (FIGS. 12A and 12B). The opening 182 may be a small opening provided only in an area of the right surface 35 corresponding to the sheet accommodation space 15.

The vertical-slide-type cover 905 is a rectangular plate (flat plate). The vertical-slide-type cover 905 is held to be movable up and down by a pair of guide rails (not depicted) arranged on the front and the rear to the vertical-slide-type cover 905, in a state in which the thickness direction of the vertical-slide-type cover 905 matches the left/right direction 9. The vertical-slide-type cover 905 moves in the up/down direction 7 (that is, the direction extending within a plane orthogonal to the left/right direction 9) while keeping a state in which the thickness direction of the vertical-slide-type cover 905 matches the left/right direction 9.

The vertical-slide-type cover 905 closes the opening 182 in a state that the thickness direction of the vertical-slide-type cover 905 matches the left/right direction 9, in the pulled down position (in the close position; FIG. 12A). The vertical-slide-type cover 905 is disposed above the opening 182 in a state that the thickness direction of the vertical-slide-type cover 905 matches the left/right direction 9, in the lifted up position (in the open position; FIG. 12B).

In this modified embodiment, the vertical size of the opening 182 and the vertical size of the vertical-slide-type cover 905 are both smaller than the vertical size L2 of the casing 14. Therefore, even with the vertical-slide-type cover 905 in the lifted up position (the open position), the vertical-slide-type cover 905 is restrained from much projection above the casing 14. Note that the vertical-slide-type cover 905 may be configured not to project above the casing 14 when the vertical-slide-type cover 905 is in the lifted up position (the open position). In particular, for example, the vertical size of the opening 182 and the vertical size of the vertical-slide-type cover 905 are sized to be smaller than half of the vertical size L2 of the casing 14.

The casing 14 may be arranged in use such that the spindle 19 may extend in the horizontal direction.

(6) Link-Type Cover

A link-type cover 906 may be provided to open and close the opening 182.

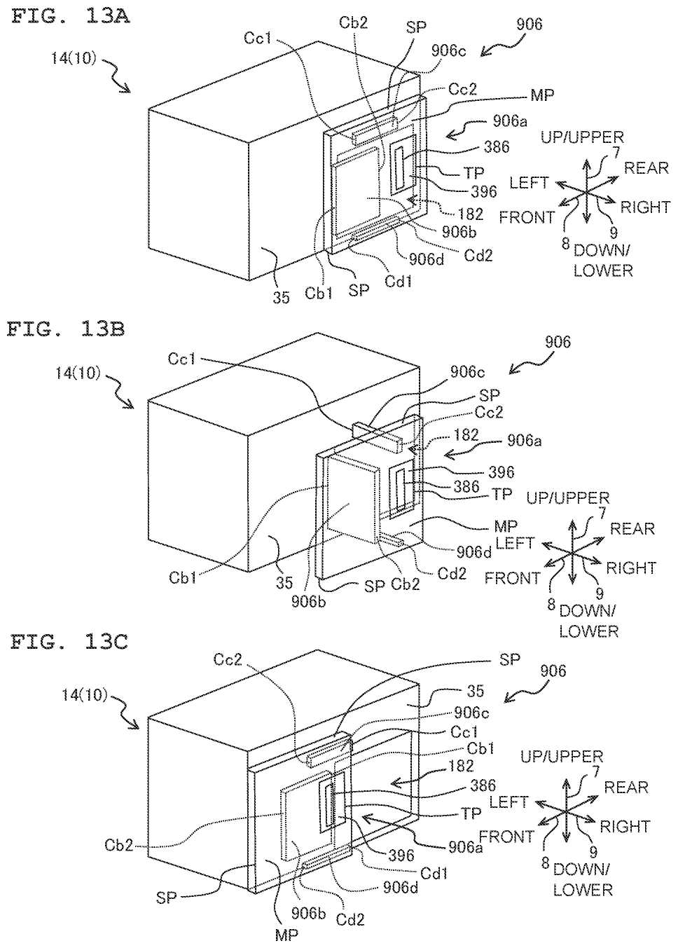

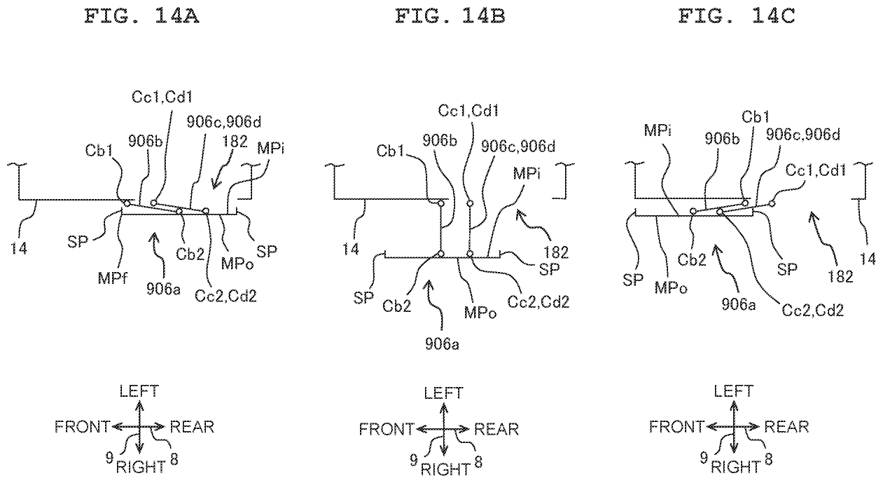

The link-type cover 906 is, as depicted in FIGS. 13A to 13C and FIGS. 14A to 14C, constructed from a cover 906a; and a front link member 906b, a first rear link member 906c, and a second rear link member 906d, linking the cover 906a to the casing 14.

The cover 906a includes an approximately square main plate MP, and four side plates SP standing up from the four sides of the main plate MP on the side of an inner surface MPi of the main plate MP (FIGS. 14A to 14C). The main plate MP and the four side plates SP may each be plate (flat plate).

The main plate MP is provided with a window 396 to allow the user of the print device 10 to observe from the outside how much sheet is left on the roll body 11 supported on the spindle 19. The window 396 is formed by fitting a transparent member TP in a through part penetrating through the main plate MP in the thickness direction.

The transparent member TP is formed with a handle 386 for the user of the print devicel0 to handle the link-type cover 906. The handle 386 projects or recesses from an outer surface MPo of the main plate MP. In this manner, by integrally forming the handle 386 for the transparent member TP for forming the window 396, it is possible to reduce the number of components, thereby lessening the manufacturing cost and processes. Note that the window 396 and the handle 386 are omitted in illustration from FIG. 14A to FIG. 14C.

The front link member 906b, the first rear link member 906c, the second rear link member 906d link the cover 906a and the casing 14 in a relatively movable manner.

The front link member 906b is a rectangular plate-like member, being arranged with the long side direction along the up/down direction 7. One of the long sides of the front link member 906b is linked via a linking part (connected part) Cb1 to the right surface 35 of the casing 14 in a pivotal manner about a shaft extending in the up/down direction 7. The other long side of the front link member 906b is linked via a linking part Cb2 to the inner surface MPi of the main plate MP in a pivotal manner about another shaft extending in the up/down direction 7. The linking part Cb1 is positioned on the front to the opening 182 (on the side of the open position), whereas the linking part Cb2 is positioned in an approximately central part of the main plate MP in the front/rear direction 8.

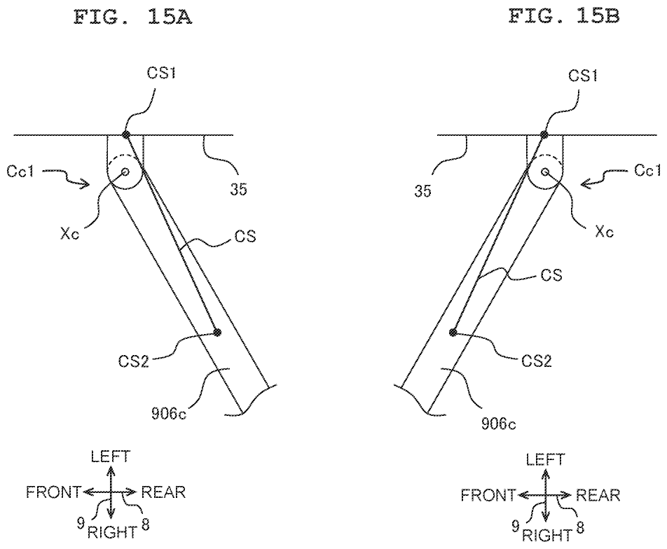

The first rear link member 906c is a rectangular plate-like member, being arranged with the short side direction along the up/down direction 7. One of the short sides of the first rear link member 906b is linked via a linking part Cc1 to the right surface 35 of the casing 14 in a pivotal manner about a shaft Xc extending in the up/down direction (FIGS. 15A and 15B). The other short side of the first rear link member 906c is linked via a linking part Cc2 to the inner surface MPi of the main plate MP in a pivotal manner about another shaft extending in the up/down direction 7. The linking part Cc1 is positioned on the rear to the linking part Cb1 and above the opening 182. The linking part Cc2 is positioned on the rear to the linking part Cb2.

Between the first rear link member 906c and the right surface 35 of the casing 14, a coil spring CS is provided (FIGS. 15A and 15B). A linking part CS1 between one end of the coil spring CS and the right surface 35 is positioned on the left to the shaft Xc of the linking part Cc1, while a linking part CS2 between the other end of the coil spring CS and the first rear link member 906c is on the first rear link member 906c. The coil spring CS assists the cover 906a for its movement when the cover 906a moves between the open position and the close position (details will be described later on).

The second rear link member 906d is an elongated bar-like member. One end of the second rear link member 906d is linked via a linking part Cd1 to the right surface 35 of the casing 14 in a pivotal manner on a shaft extending in the up/down direction. The other end of the second rear link member 906d is linked via a linking part Cd2 to the inner surface MPi of the main plate MP, pivotally on a shaft extending in the up/down direction 7. The linking part Cd1 is positioned on the rear to the linking part Cb1 and below the opening 182. The linking part Cd2 is positioned on the rear to the linking part Cb2.

The front link member 906b, the first rear link member 906c, and the second rear link member 906d are the same in length with each other in the direction over between the casing 14 and the cover 906a (to be referred to below as extending direction). That is, the front link member 906b, the first rear link member 906c, and the second rear link member 906d construct a parallel link mechanism to relatively move the casing 14 and the cover 906a with the right surface 35 and the main plate MP being kept parallel to each other.

The link-type cover 906 is movable between the close position for the cover 906a to cover up the opening 182 (FIGS. 13A and 14A), and the open position to arrange the cover 906a on the front to the opening 182 (FIGS. 13C and 14C), along the plane orthogonal to the left/right direction 9.

When the cover 906a is in the close position, the main plate MP of the cover 906a is orthogonal to the left/right direction 9. Further, the front link member 906b, the first rear link member 906c, and the second rear link member 906d are arranged parallel to each other and the linking parts Cb1, Cc1, and Cd1 are arranged to be on the front to the linking parts Cb2, Cc2, and Cd2, respectively.

In this modified embodiment, the front link member 906b has a smaller length in the extending direction than the length between the linking part Cb2 and the front end MPf of the main plate MP (FIG. 14A). Therefore, when the cover 906a is in the close position, the whole front link member 906b is covered up by the main plate MP. By virtue of this, because the front link member 906b is hidden when the cover 906a is in the close position, that is, when the print device 10 is in a usable state, it is possible to keep a nice appearance for the apparatus. Note that in this modified embodiment, when the cover 906a is in the close position, the front link member 906b, the first rear link member 906c, and the second rear link member 906d are accommodated in a space enclosed by the right surface 35 of the casing 14, the main plate MP and the side plates SP of the cover 906a.

When the cover 906a is in the close position, the shaft Xc of the linking part Cc1 is positioned on the front to the line linking the linking part CS1 and the linking part CS2 (FIG. 15A). Therefore, the coil spring CS biases the first rear link member 906c in the counterclockwise direction as viewed from above and, furthermore, biases the cover 906a toward the close position. Therefore, the user who moves the cover 906a from the close position to the open position shall resist the biasing force of the coil spring CS to pull the cover 906a frontward.

With the cover 906a being pulled frontward, the front link member 906b, the first rear link member 906c, and the second rear link member 906d are kept parallel to each other as they are, while pivoting with respect to the casing 14 and the cover 906a, whereas the cover 906a moves frontward and rightward. Because the front link member 906b, the first rear link member 906c, and the second rear link member 906d are equal in length to each other, the cover 906a moves while keeping a posture in which the cover 906a is orthogonal to the left/right direction 9.

With the front link member 906b, the first rear link member 906c, and the second rear link member 906d whose extending directions are along the left/right direction 9 (FIGS. 13B and 14B), the distance between the cover 906a and the right surface 35 reaches to the maximum. This distance is almost equal to the length of the front link member 906b, the first rear link member 906c, and the second rear link member 906d in the extending direction.

From the state depicted in FIGS. 13B and 14B, if the cover 906a is further moved frontward, then the shaft Xc of the linking part Cc1 moves to the rear to the line linking the linking part CS1 and the linking part CS2 (FIG. 15B). By virtue of this, the coil spring CS comes to bias the first rear link member 906c in the clockwise direction as viewed from above and, furthermore, to bias the cover 906a to the open position. Hence, the user moving the cover 906a from the close position to the open position can easily cause the cover 906a to reach to the open position with the assistance of the biasing force of the coil spring CS. In this manner, with the coil spring CS being provided, because the cover 906a is biased toward the open position or the close position, the cover 906a is restrained from stopping in a midway position between the open position and the close position, such that the cover 906a may be maintained either in the open position or in the close position stably.

When the cover 906a is in the open position, the cover 906a is also orthogonal to the left/right direction 9. Further, the front link member 906b, the first rear link member 906c, and the second rear link member 906d are arranged to be parallel to each other and to let the linking parts Cb1, Cc1, and Cd1 be positioned on the rear to the linking parts Cb2, Cc2, and Cd2, respectively. Because the linking part Cc1 is positioned above the opening 182 and the linking part Cd2 is positioned below the opening 182, the first rear link member 906c and the second rear link member 906d are arranged outside of the opening 182. Therefore, the user can favorably replace the roll body 11 via the opening 182 without interference from the first rear link member 906c and the like.

In this manner, according to the link-type cover 906, when moving the cover 906a between the close position and the open position, it is possible to restrain the cover 906a from heading out rightward no more than the length of each linking member in the extending direction, thereby needing a small space for opening and closing the cover. Further, because there is no need to provide a rail and the like for move the cover for the opening of the casing 14, the user can replace the roll body 11 favorably without the rail and the like of the opening in his/her way during the work.

Note that the front link member 906b, the first rear link member 906c, and the second rear link member 906d may be changed as appropriate in terms of their shapes and the like. In particular, for example, either the first rear link member 906c or the second rear link member 906d may be omitted. Further, the front link member 906b and the first rear link member 906c may be long bar-like members. It is desirable to configure such that with a pair of linking members aligning in the front/rear direction, the cover 906a may be moved between the open position and the close position while being kept parallel to the left/right direction 9. However, there is no limitation thereto. Further, it is possible to use such a configuration as to let the pivotal shafts of the linking members be along the front/rear direction 8 to position the cover 906a in the open position above the opening 182.

It is not necessary to arrange the position of the linking part CS1 between the coil spring CS and the right surface 35 of the casing 14 in the front/rear direction 8 to conform with the position of the shaft Xc in the front/rear direction 8, but it is possible to arrange the linking part CS1 to deviate frontward or rearward from the shaft Xc. By arranging the linking part CS1 on the front (rear) to the shaft Xc, it is possible to further increase the force to bias the cover 906a toward the close position (the open position). Instead of the coil spring CS, any other biasing member may be used such as an elastic resin or the like, or the coil spring CS may as well be omitted. A biasing member such as the coil spring CS or the like may be provided to the front link member 906b or the second rear link member 906d.

Instead of a parallel link mechanism, it is also possible to apply a configuration in which a length of the front link member 906b in the extending direction is different from the lengths of the first rear link member 906c and the second rear link member 906d in the extending direction. In such case, the main plate MP moving between the close position and the open position and the main plate MP in the open position are postured oblique to the main plate MP in the close position.

In the above embodiment and each modified embodiment, the cover moves from the close position to the open position without much heading out rightward. This is because the cover moves between the close position and the open position without much changing the posture.

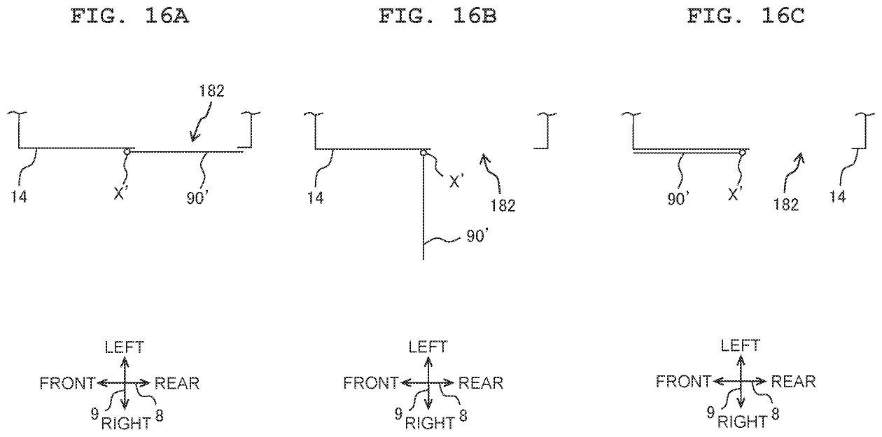

FIGS. 16A to 16C depict a comparative example where a plate-like cover 90′ is fitted to the right surface 35 of the casing 14 about a revolving shaft X′ extending in the up/down direction 7. In the course of the cover 90′ moving between the close position (FIG. 16A) blocking (covering) the opening 182 and the open position (FIG. 16C) opening (uncovering) the opening 182, this comparative example's cover 90′ assumes a posture (FIG. 16B) orthogonal to that of the cover 90′ when in the close position. In this manner, if the cover changes much in posture, then the cover 90′ projects much rightward such that a larger surrounding space is needed for the print device 10 to open and close the cover.

Compared to the above, in the above embodiment and each modified embodiment, the cover includes a plate part (flat plate part) covering at least part of the opening when the cover is in the close position (for example, the cover right surface 91 of the slide cover 90; the main plate MP of the link-type cover 906), and the angle formed between the plane parallel to the plate part in the close position (the second plane) and the plane parallel to the plate part between the close position and the open position (the first plane) is less than 90 degrees when the cover is in any position between the open position and the close position (that is, any position which the cover can take in moving from the open position to the close position but which does not include the open position and the close position). The cover maintains or keeps a posture in which the angle between the first plane and the second plane is less than 90 degrees, in the course of moving from the open position to the close position.

In particular, for example, in the embodiment provided with the slide cover 90, the cover right surface 91 (the plate part) is orthogonal to the left/right direction 9 in any of the close position, the open position, and an arbitrary position between the close position and the open position. That is, the first plane is constantly parallel to the second plane. Much the same is true on the slide cover pair 901, the pivot-type cover 903, the vertical-slide-type cover 905, and the link-type cover 906 included in the modified embodiments, respectively.

In the above embodiment and each modified embodiment, the angle formed between the second plane parallel to the plate part in the close position and the first plane parallel to the plate part in any position between the close position and the open position may be kept at 20 degrees or less or kept at 3 degrees or less. In other words, in the course of moving from the close position to the open position, the cover may maintain a posture in which the angle formed between the first plane and the second plane is 20 degrees or less, or 3 degrees or less. Further, the angle formed between the second plane and a third plane parallel to the plate part in the open position may be kept at 20 degrees or less or kept at 3 degrees or less. Further, at least two of the second plane, any one or all of the first planes, and the third plane may be parallel to each other. By keeping the angle at a small value between the second plane parallel to the plate part in the close position, and the first plane parallel to the plate part positioned between the close position and the open position, it is possible to suppress the change amount of the posture of the cover when being opened and closed. By virtue of this, the space needed for opening and closing the cover for the print device becomes small.

In the above embodiment and each modified embodiment, the plate part of the cover in the close position is orthogonal to the left/right direction 9. However, without being limited to that, the plate part such as the cover right surface 91 of the slide cover 90 or the main plate MP of the cover 906a may not be orthogonal to the left/right direction 9. For example, it is possible to apply such an arbitrary configuration as the upper end being positioned on the left to the lower end, the front end being positioned on the left to the rear end, or the like.

In the above embodiment and each modified embodiment, the plate part of the cover in the close position covers the entire area of the opening. However, without being limited to that, the plate part such as the cover right surface 91 of the slide cover 90 or the main plate MP of the cover 906a may cover only part of the opening. In such cases, another part than the plate part in the cover (such as a curved plate part or the like) comes to cover the other area of the opening.

Further, the opening 18 of the casing 14 may be formed across the left surface 36 and the upper surface 33 but not in the right surface 35. The opening 181 and the opening 182 of the casing 14 may be formed in the left surface 36 but not in the right surface 35.

The cover in each of the above modified embodiments may be provided with an equivalent structure to the handle 38 and/or the window 39. Alternatively, the cover in each of the above embodiment and modified embodiments may be provided with a handle and a window formed by a single member such as the handle 386 and the window 396.

The cover in each of the above modified embodiments may be provided with an equivalent cam ditch to the cam ditch 94 and, with this cam ditch and the pin 69, a cam mechanism may be constructed to move the pinch roller 61 up and down according to opening or closing the cover.

The cover in each of the above modified embodiments may be provided with an equivalent vent to the vent 93. This vent may be provided to overlap with the air outlet port 12 of the casing 14 when the cover of each modified embodiment is in the open position.

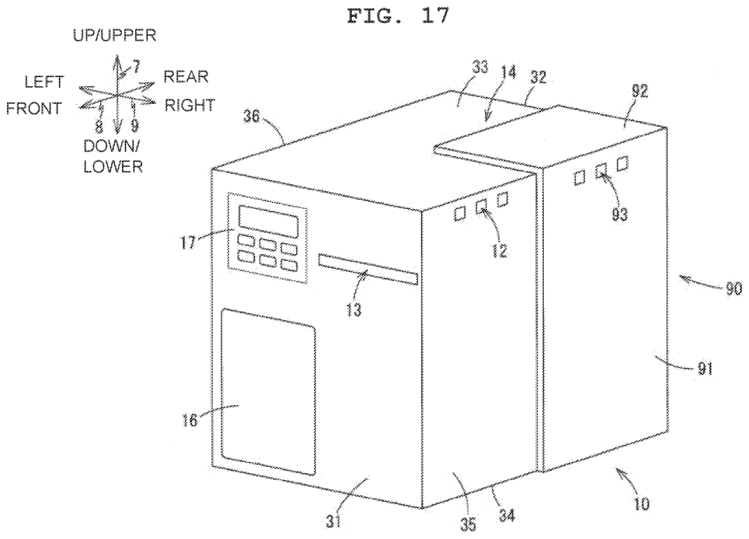

Further, as depicted in FIG. 17, the air outlet port 12 of the casing 14 may be formed in the right surface 35 instead of the upper surface 33. In such case, the vent 93 of the slide cover 90 is formed in the cover right surface 91 instead of the cover upper surface 92. Further, the shape, arrangement (pitch) and the like of the air outlet port 12 and the vent 93 may be changed as appropriate. Much the same is true on the vent formed in the cover of each modified embodiment.

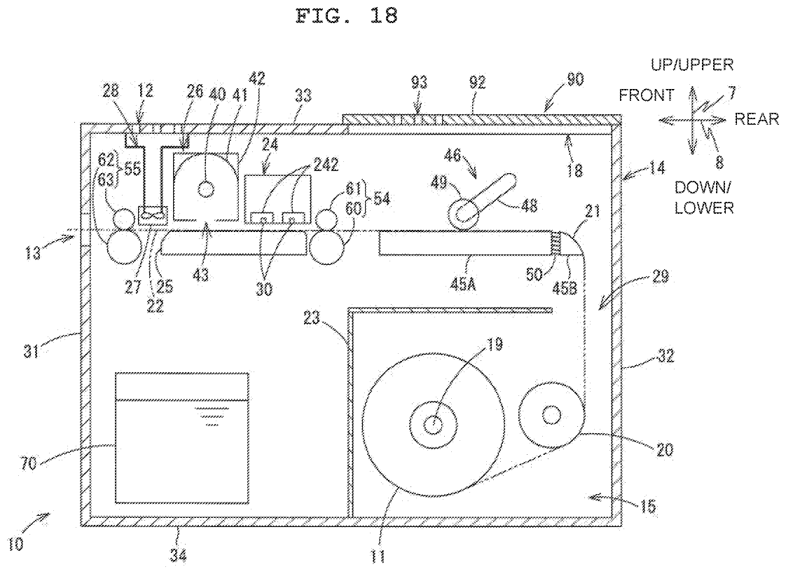

Further, as depicted in FIG. 18, the sheet guide 45 may be constructed from two members: a plate-like first guide member 45A and a second guide member 45B having a curved surface facing above and the rear. The second guide member 45B is linked with the first guide member 45A via a coil spring 50, to be movable along the front/rear direction 8. With the second guide member 45B being biased rearward by the coil spring 50, the sheet guide 45 functions as a tensioner to apply a tension to the sheet.

Further, in the above embodiment, in the conveyance path 22, the first conveyance roller pair 54 and the second conveyance roller pair 55 nip and convey the sheet. However, instead of that, another conveyance member may be used such as a conveyance belt or the like.

Further, in the above embodiment, the air in the inner space of the casing 14 is discharged forcibly by the fan 27. However, the fan 27 may not be provided and thus the air in the inner space of the casing 14 may be discharged through the air outlet port 12 by a natural flow of the air and the like.

Further, the tank 70 is not limited to storing the black ink of the one color but, for example, may store inks of four colors of black, yellow, cyan and magenta, respectively. Further, it is possible to use an ink containing a resin cured by ultraviolet rays. In such case, instead of the heater 26, an ultraviolet radiator (an example of the light source) may be used.

Further, in the above embodiment, the printing head 24 which prints on the sheet by an ink jet method is used as a printing unit. However, a thermal head or an electrophotography printing method may be adopted instead of that. In such cases, if not necessary, the heater 26 may be omitted.

Further, in the above embodiment, the roll body 11 is supported on the spindle 19. However, unlike the spindle 19, a bar-like support member which supports the roll body rotatably may not be rotatable.

Further, the discharge port 13 is not necessarily formed in the front surface 31 of the casing 14. For example, the discharge port 13 may be formed in the upper surface 33 of the casing 14 whereby the printed sheet passing through the discharge port 13 may be discharged upward or obliquely upward.

Further, the aforementioned print device 10 is used with the front surface 31 and the rear surface 32 of the casing 14 along the up/down direction 7 and the left/right direction 9. However, the print device 10 is not limited to that posture in use.

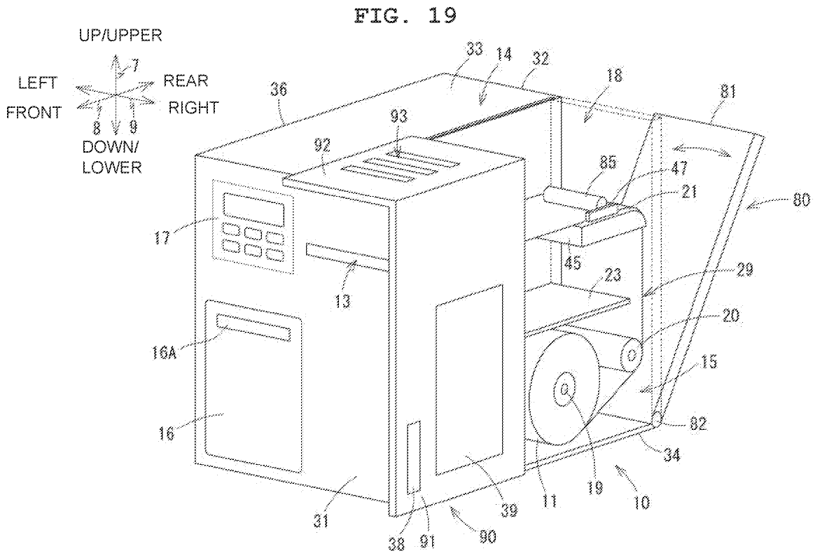

Further, as depicted in FIG. 19, the casing 14 may be provided with a pivot cover 80 (an example of the second cover) in addition to the slide cover 90 (an example of the first cover). The pivot cover 80 is formed as part of the rear surface 32 being the outer wall of the casing 14, in the close position (the posture depicted in FIG. 19 with the solid line). Therefore, the pivot cover 80 is positioned on the rear to the printing head 24 in the front/rear direction 8, that is, on the upstream side to the printing head 24 in the conveyance orientation. Further, an upper end 81 of the pivot cover 80 (an example of the one end) defines the rear end of the opening 18 of the casing 14.

The pivot cover 80 is linked with the casing 14 via a pivot shaft 82 in the vicinity of the rear end of the lower surface 34 of the casing 14. The pivot shaft 82 extends along the left/right direction 9. The pivot cover 80 is pivotable about the pivot shaft 82 with an upper end part 81 as the pivot leading end (a tip of the pivot movement). As depicted in FIG. 19 with the solid line, the upper end part 81 of the pivot cover 80 in an opened posture is positioned on the rear to and below the upper end part 81 of the pivot cover 80 in a closed posture. With the pivot cover 80 in the opened posture, a space is expanded on the rear to the spindle 19 and the sheet guide 45. By virtue of this, the space is expanded for pulling the sheet out from the roll body 11 installed on the spindle 19 as far as to the sheet guide 45, and setting the sheet to the sheet guide 45.

Further, as depicted in FIG. 19, instead of the presser member 46, a pressing roller 85 may be provided. The pressing roller 85 is positioned above the sheet guide 45. The axial line of the pressing roller 85 is along the left/right direction 9. Although being not depicted in FIG. 19, the pressing roller 85 is movable along the up/down direction 7, and biased downward by a biasing member such as a spring or the like. Between the pressing roller 85 and the upper surface of the sheet guide 45, the sheet pulled out of the roll body 11 is passible. When a new roll body 11 is installed on the spindle 19, the pressing roller 85 is moved upward. The upward movement of the pressing roller 85 is realized, for example, by moving and/or revolving of a support member supporting the shaft of the pressing roller 85.

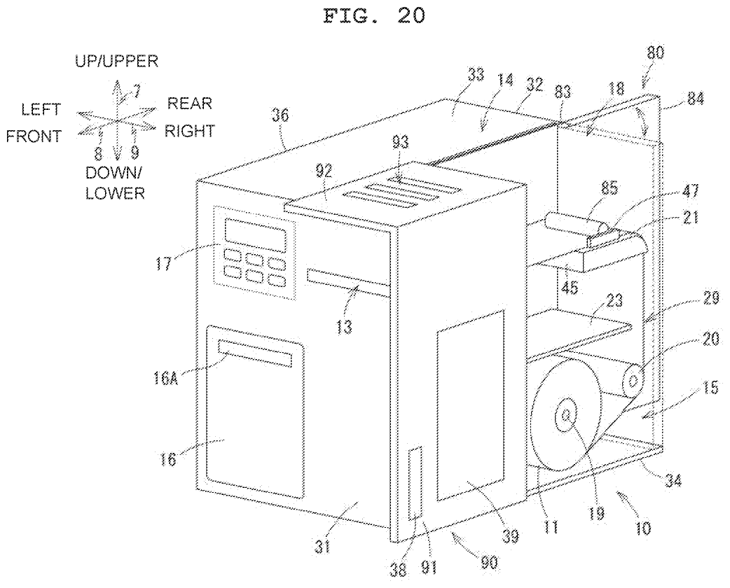

Further, as depicted in FIG. 20, the pivot cover 80 may be linked with the casing 14 via the pivot shaft 83 in the vicinity of the center of the rear surface 32 of the casing 14 in the left/right direction 9. The pivot shaft 83 extends along the up/down direction 7. In such case, a right end part 84 of the pivot cover 80 (an example of the one end) defines the rear end of the opening 18 of the casing 14. The pivot cover 80 is pivotable on the pivot shaft 83 with the right end part 84 as the revolving leading end (a tip of the pivot movement). As depicted in FIG. 20 with the solid line, the right end part 84 of the pivot cover 80 in the opened posture is positioned on the rear and left to the right end part 84 of the pivot cover 80 in the closed posture (depicted in FIG. 20 with the broken line). With the pivot cover 80 in the opened posture, the space is expanded on the rear to the spindle 19 and the sheet guide 45. By virtue of this, the space is expanded for pulling the sheet out from the roll body 11 installed on the spindle 19 as far as to the sheet guide 45, and setting the sheet to the sheet guide 45.

Note that the pivot cover 80 depicted in FIGS. 19 and 20 pivots to change the posture relative to the casing 14. However, instead of the pivot cover 80, a second cover may be provided on the casing 14 to change the posture relative to the casing 14 by way of another motion than pivoting. For example, the second cover formed as part of the rear surface 32 constructing (constituting) the rear wall of the casing 14 may be configured such that the space behind the spindle 19 and the sheet guide 45 is expanded by sliding the second cover relative to the casing 14 in the left/right direction 9. Further, the second cover may be removable from the casing 14.

What is claimed is:

1. A print device comprising:
a casing having an inner space;
a support which extends along a first direction in the inner space of the casing and which is configured to rotatably support a roll body;
a conveyer configured to convey a sheet pulled out of the roll body supported by the support in a conveyance orientation along a second direction orthogonal to the first direction, in the inner space of the casing;
a print unit configured to perform a print by causing a print matter to adhere to the sheet conveyed in the conveyance orientation, in the inner space of the casing; and
a cover,
wherein an opening is provided on the casing such that the inner space is exposed to an outside of the casing via the opening, and
the cover is configured to slide relative to the casing along the second direction between an open position in which the opening is uncovered and a close position in which the opening is covered by the cover.

2. The print device according to claim 1, wherein the print unit is not exposed to the outside of the casing through the opening of the casing.

3. The print device according to claim 1, wherein the casing has a first surface and a second surface positioned apart in the first direction, a third surface and a fourth surface positioned apart in a third direction orthogonal to the first direction and the second direction so as to connect the first surface and the second surface, and a fifth surface and a sixth surface positioned apart in the second direction so as to connect the third surface and the fourth surface;
the opening is continuously provided on the third surface and one of the first surface and the second surface; and
the cover has a seventh surface parallel to the one of the first surface and the second surface on which the opening is provided, and an eighth surface parallel to the third surface.

4. The print device according to claim 3, wherein a distance between the third surface and the fourth surface is longer than a distance between the first surface and the second surface.

5. The print device according to claim 3, wherein the cover positioned in the open position is positioned downstream side in the conveyance orientation of the cover positioned in the close position.

6. The print device according to claim 5, wherein the casing has an air outlet port penetrating through the third surface;
the cover has a vent penetrating through the eighth surface; and
in a case that the cover is positioned in the open position, the air outlet port overlaps with the vent as seen in the third direction.

7. The print device according to claim 6, wherein in a case that the cover is positioned in the close position, the air outlet port is positioned downstream side in the conveyance orientation of the print unit and the vent is positioned upstream side in the conveyance orientation of the print unit.

8. The print device according to claim 6, wherein the third direction is an up-down direction, and the third surface is positioned above the fourth surface.

9. The print device according to claim 6, further comprising a fan positioned in the inner space of the casing,
wherein the fan is configured to exhaust air to the outside of the casing through the air outlet port.

10. The print device according to claim 9, further comprising a duct which is positioned in the inner space of the casing and through which the air sent out by the fan flows,
wherein the inner space of the casing and the outside of the casing are in communication with each other through the duct and the air outlet port.

11. The print device according to claim 6, wherein the print unit is configured to discharge a liquid as the print matter to the sheet.

12. The print device according to claim 6, further comprising a heater configured to heat the print matter and/or the sheet on which the print matter has been adhered.

13. The print device according to claim 6, further comprising a light source configured to irradiate the print matter with an ultraviolet ray.

14. The print device according to claim 5, wherein the conveyer includes a roller pair configured to nip the sheet, and
the print device further comprising a cam mechanism configured to separate a first roller of the roller pair from a second roller of the roller pair depending on a slide movement of the cover from the close position to the open position.

15. A print device comprising:
a casing having an inner space;
a support which extends along a first direction in the inner space of the casing and which is configured to rotatably support a roll body;
a conveyer configured to convey a sheet pulled out of the roll body supported by the support in a conveyance orientation along a second direction orthogonal to the first direction, in the inner space of the casing;
a print unit configured to perform a print by causing a print matter to adhere to the sheet conveyed in the conveyance orientation, in the inner space of the casing;
a first cover; and
a second cover,
wherein an opening is provided on the casing such that the inner space is exposed to an outside of the casing via the opening;
the first cover is configured to slide relative to the casing along the second direction between an open position in which the opening is uncovered and a close position in which the opening is covered by the first cover;
the second cover constitutes at least a portion of an outer wall, of the casing, positioned at one side in the second direction of the casing;
the second cover has one end defining a part of the opening; and
the second cover is configured to change a posture of the second cover relative to the casing.

16. The print device according to claim 15, wherein the second cover is configured to pivot in a manner that the one end defining the part of the opening is a tip of a pivot movement.

17. The print device according to claim 16, wherein the second cover is configured to pivot on a pivot axis extending along the first direction.

18. The print device according to claim 16, wherein the second cover is configured to pivot on a pivot axis extending along a third direction orthogonal to the first and second directions.

19. The print device according to claim 15, wherein the second cover is positioned upstream side in the conveyance orientation of the print unit.

20. The print device according to claim 15, wherein the print unit is not exposed to the outside of the casing through the opening of the casing.

21. A print device comprising:
a casing having an inner space;
a support which extends along a first direction in the inner space of the casing and which is configured to rotatably support a roll body;
a print unit configured to perform a print, in the inner space of the casing, on a sheet pulled out of the roll body supported by the support; and
a cover,
wherein the support is configured to support the roll body such that the roll body rotates on a rotation axis extending in the first direction;
an opening is provided on the casing such that the inner space is exposed to an outside of the casing via the opening;
the cover is configured to move between an open position in which the opening is uncovered and a close position in which the opening is covered by the cover;
the cover includes a plate configured to cover at least a portion of the opening in a case that the cover is positioned in the close position; and
the cover is configured to maintain a posture in which an angle between a first plane parallel with the plate of the cover and a second plane parallel with the plate of the cover positioned in the close position is less than 90 degrees throughout a movement from the close position to the open position.

22. The print device according to claim 21, wherein the cover is configured to maintain a posture in which the angle between the first plane and the second plane is not more than 20 degrees throughout the movement from the close position to the open position.

23. The print device according to claim 21, wherein the cover is configured to maintain a posture in which the angle between the first plane and the second plane is not more than 3 degrees throughout the movement from the close position to the open position.

24. The print device according to claim 21, wherein an angle between the second plane and a third plane parallel with the plate of the cover positioned in the open position is not more than 20 degrees.

25. The print device according to claim 21, wherein the plate of the cover positioned in the close position is orthogonal to the first direction.

26. The print device according to claim 21, wherein, in a case that the print device is in use, the first direction matches a horizontal direction, and
the cover is configured to slide in a second direction in at least a portion of a path between the open position and the close position, the second direction being orthogonal to the first direction and matching, in a case that the print device is in use, the horizontal direction.

27. The print device according to claim 26, wherein the cover has a first cover configured to slide from the close position to the open position in a first orientation in the second direction, and a second cover configured to slide from the close position to the open position in a second orientation, opposite to the first orientation, in the second direction.

28. The print device according to claim 21, wherein the plate includes a plurality of plate parts connected to each other pivotally;
in a case that the cover is positioned in the close position, the plurality of plate parts is arranged on one plane; and
in a case that the cover is positioned in the open position, the plurality of plate parts is arranged to overlap with each other.

29. The print device according to claim 21, wherein the cover pivots on a shaft extending in the first direction, between the open position and the close position.

30. The print device according to claim 21, wherein the plate includes a plurality of slats, and the cover is a shutter in which the plurality of slats is connected pivotally.

31. The print device according to claim 21, wherein, in a case that the print device is in use, the first direction matches a horizontal direction, and
the cover is configured to slide in a second direction between the open position and the close position, the second direction being orthogonal to the first direction and matching, in a case that the print device is in use, the vertical direction.

32. The print device according to claim 21, further comprising:
a first link connected to each of the casing and the cover so as to pivot on a shaft extending in a second direction orthogonal to the first direction; and
a second link connected to each of the casing and the cover so as to pivot on a shaft extending in the second direction,
wherein the first link is arranged at an open position side, of the second link member, on which the open position defined.

33. The print device according to claim 32, wherein a length of the first link in a direction extending between the casing and the cover is smaller than a length between an end of the cover at the open position side and a connected part between the first link and the cover, and
the first link is connected to the casing at the open position side of the opening.

34. The print device according to claim 32, wherein the second direction is an up-down direction, and the second link is arranged above the opening.

35. The print device according to claim 32, further comprising a biasing member which has a first end connected to the casing and a second end connected to the first link or the second link, and which is configured to bias the first link or the second link to the casing, wherein
a connected part between the bias member and the casing is positioned, in the first direction, at an opposite side of a connected part between the bias member and the first link or the second link with respect to a pivot axis of the first link or the second link relative to the casing.

36. The print device according to claim 21, wherein the cover is provided with a through part penetrating through the cover in the first direction, and the through part is provided with a transparent member.

37. The print device according to claim 36, wherein the transparent member is provided with a handle configured such that a user of the print device handles the cover with the handle.
